(19) United States
(12) Patent Application Publication
(10) Pub. No.: US 2014/0345910 A1
(43) Pub. Date: Nov. 27, 2014

(54) METHOD OF FORMING CONDUCTIVE LINE, AND DEVICE COMPRISING THE SAME

(71) Applicant: InnoLux Corporation, Miao-Li County (TW)

(72) Inventors: Ya-Leng WANG, Miao-Li County (TW); Hung-Sheng CHO, Miao-Li County (TW); Tung-Chang TSAI, Miao-Li County (TW)

(73) Assignee: InnoLux Corporation, Miao-Li County (TW)

(21) Appl. No.: 14/267,229

(22) Filed: May 1, 2014

(30) Foreign Application Priority Data
May 21, 2013 (TW) 102117913

(51) Int. Cl. H05K 1/09; H05K 3/12

(52) U.S. Cl. CPC H05K 1/092; H05K 3/1283; H05K 2201/0137; H05K 2201/0326
USPC 174/251; 174/257; 427/553

(57) ABSTRACT

The present invention relates to a method for forming a conductive line, and a device comprising the conductive line. The method for forming a conductive line comprises: (A) providing a metal oxide composition which comprises a metal oxide, and a reducing agent; (B) applying the metal oxide composition on a substrate, and curing the metal oxide composition to form an metal oxide layer; and (C) irradiating the metal oxide layer by a light source to occur a chemical reduction reaction between the metal oxide and the reducing agent in the metal oxide layer to proceed to thereby form a conductive line.

### CROSS REFERENCE TO RELATED APPLICATION

This application claims the benefits of the Taiwan Patent Application Serial Number 102117913, filed on May 21, 2013, the subject matter of which is incorporated herein by reference.

### BACKGROUND OF THE INVENTION

1. Field of the Invention

The present invention relates to a method for forming a conductive line and a device comprising the same.

2. Description of Related Art

With the rapid development of electronic industry, electronic products are trending towards miniaturization and lightweight, and the process improvement is also an important research aim in the industry. All electronic products contain various forms of conductive lines, and the typical method for forming a conductive line includes printing, build-up, photolithography and etching methods. In the inkjet printing method, the most common printing technique, the ink containing a conductive material is sprayed by a nozzle under the control of a controller to form a circuit pattern, and unnecessary ingredients in the ink are then removed by sintering, leaving the conductive material to form the conductive line.

However, the high-temperature sintering makes the inkjet printing undesirable for use in plastic or other flexible substrates, and the resulting conductive line also suffers from poor resolution. The photolithography and etching methods generally include steps of exposure, development, etching, and stripping. Although the photolithography and etching methods belong to a low temperature process, it has the disadvantages of complicated process, low throughput, high cost, and being environmentally unfriendly.

In preparing a capacitive touch panel, for example, if an insulating layer on the X-axis and Y-axis electrodes, and a bridging conductive layer on the insulating layer for bridging the Y-axis electrode, are to be formed, two acts of the photolithography and etching process are required. The overall production flow is rather complicated and has low throughput and high cost. Accordingly, it is desirable to provide a simplified method for forming a conductive line which is applicable to a variety of electronic devices to increase throughput and reduce costs.

### SUMMARY OF THE INVENTION

An object of the present invention is to provide a method for forming a conductive line, comprising: (A) providing a metal oxide composition which comprises a metal oxide and a reducing agent, wherein the reducing agent is at least one selected from a group consisting of a polyol, a hydroxyl alcohol, an aldehyde, a ketone, and a carboxylic acid; (B) applying the metal oxide composition on a substrate, and curing the metal oxide composition to form a metal oxide layer, wherein the metal oxide layer comprises the reducing agent; and (C) irradiating the metal oxide layer to occur a chemical reduction reaction between the metal oxide and the reducing agent in the metal oxide layer to proceed to thereby form a conductive line.

In an embodiment, the metal oxide composition comprises: 55-85 parts by weight of the metal oxide, and 5-15 parts by weight of the reducing agent.

In addition, another object of the present invention is to provide a device comprising a conductive line, wherein the conductive line comprises: a substrate; a conductive layer disposed on the substrate, wherein the conductive layer is formed by a chemical reduction reaction of a metal oxide composition, and the metal oxide composition comprises a metal oxide and a reducing agent, wherein the reducing agent is at least one selected from a group consisting of a polyol, a hydroxyl alcohol, an aldehyde, a ketone, and a carboxylic acid.

A further object of the present invention is to provide a device comprising a conductive line, wherein the conductive line comprises: a substrate; a metal oxide layer disposed on the substrate, wherein the metal oxide layer comprises a metal oxide and a reducing agent, wherein the reducing agent is at least one selected from a group consisting of a polyol, a hydroxyl alcohol, an aldehyde, a ketone, and a carboxylic acid; and a conductive layer embedded in the metal oxide layer, wherein the conductive layer comprises a metal formed by a chemical reduction reaction of the metal oxide.

### BRIEF DESCRIPTION OF THE DRAWINGS

The above and other objects, features and other advantages of the present invention will be more clearly understood from the following detailed description taken in conjunction with the accompanying drawings, in which:

FIGS. 1A-1C are schematic views showing the manufacturing process according to an embodiment of the present invention;

FIGS. 2A-2D are schematic views showing the manufacturing process according to another embodiment of the present invention;

FIGS. 3A-3D are schematic views showing the manufacturing process according to yet another embodiment of the present invention; and

FIGS. 4A-4E are schematic views showing the manufacturing process according to a further embodiment of the present invention.

### DETAILED DESCRIPTION OF THE PREFERRED EMBODIMENT

Hereinafter, embodiments of the present invention will be explained in detail with reference to the accompanying drawings.

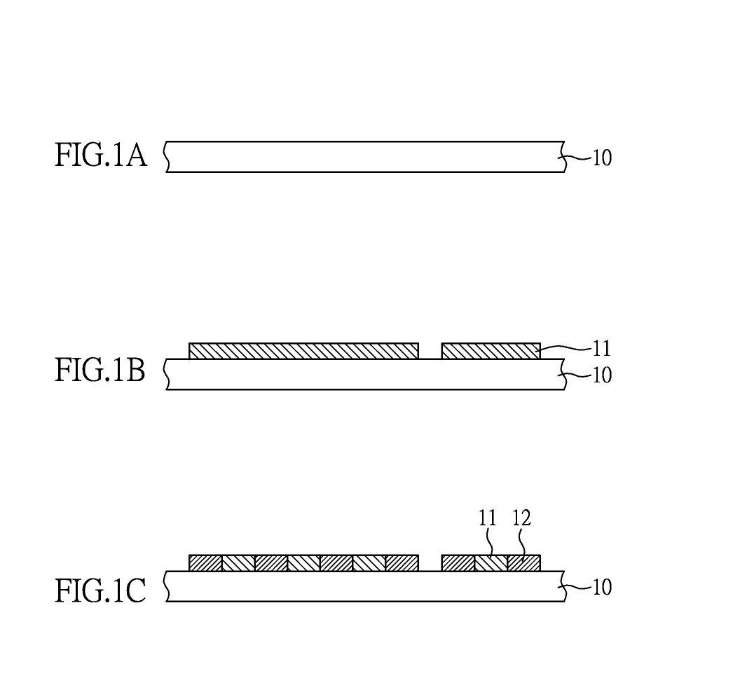

FIG. 1C illustrates the conductive line according to a preferable embodiment of the present invention. The manufacturing process thereof will be described below with reference to FIGS. 1A-1C.

As shown in FIG. 1A, a substrate 10 is provided. In this embodiment, a glass substrate is used as an example, while other common substrates in the art, such as ceramic, metal or plastic, etc., may be used. The substrate may also be a semi-product of any electronic devices to be formed with a conductive line. Although the substrate 10 may have any shape, a substrate having a planar structure is used as the example of this embodiment. Then, as shown in FIG. 1B, a metal oxide composition (not shown) is printed on the substrate 10 by screen printing, while in other embodiments, the printing method such as inkjet printing, gravure printing, relief printing, and so on may be selected according to the structure of the substrate and the desired structure of the conductive line. Next, the metal oxide composition is cured by a thermal treatment to form a patterned metal oxide layer 11; then light irradiation is performed with a photomask (not shown), wherein the type of the light source may be, for example: gas laser light, wherein the gas is selected from helium, neon, krypton, argon, xenon, radon, nitrogen, carbon monoxide, carbon dioxide, or a mixture of two gases listed above, and the like; a single-wavelength light source having a wavelength of 300 nm to 15 μm; ultraviolet (UV light) having a wavelength of less than 300 nm; and pulsed light which is provided by a multi-wavelength light source having a wavelength ranging from 550 to 1200 nm. As such, the metal oxide in the irradiated portion of the metal oxide layer 11 is converted into a corresponding metal form by chemical reduction reaction to thereby form a patterned conductive line 12. In other embodiments, any kind of light source which may provide the sufficient energy to reduce the metal oxide into metal form may be used, for example, visible light, infrared light, ultraviolet light, microwave, etc.

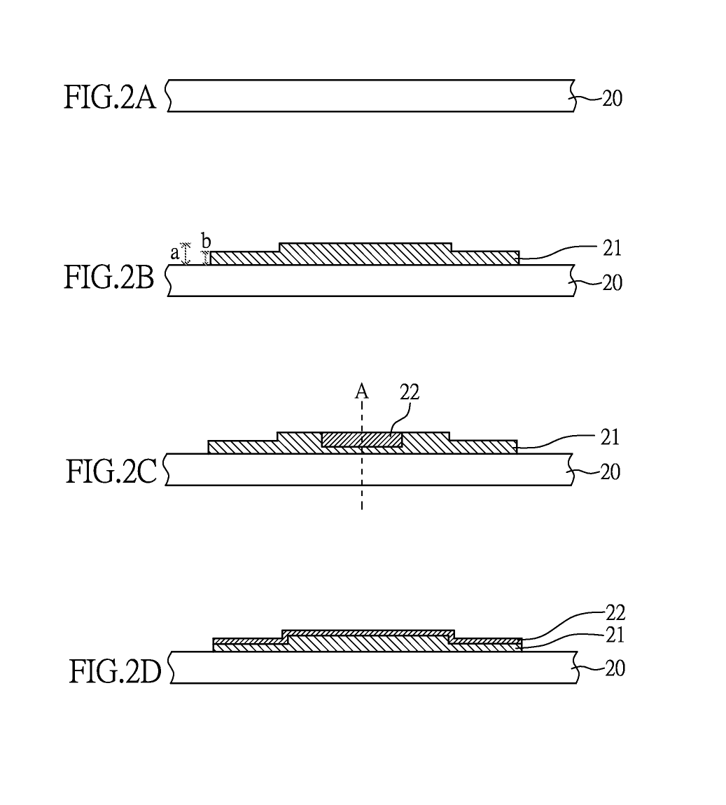

The above-described metal oxide composition contains 55-85 parts by weight of a metal oxide powder, wherein the metal oxide powder has an average particle size of 300 nm or less; parts by weight of a reducing agent; 5-30 parts by weight of an adhesive agent; 5 parts by weight or less of a dispersant; 0.1-10 parts by weight of a plasticizer; and 1 parts by weight or less of an auxiliary agent, wherein the auxiliary agent is a curing agent, a flexibilizer, or a diluent. In some embodiments, the metal oxide powder is at least one selected from a group consisting of a gold oxide, a platinum oxide, a silver oxide, a copper oxide, a nickel oxide, an aluminum oxide, and a zinc oxide. The metal oxide powder has a particle size of 15 μm or less, and preferably 100-500 nm. The reducing agent is selected from a group consisting of a polyol, a hydroxyl alcohol, an aldehyde, a ketone, and a carboxylic acid. Specifically, the reducing agent is at least one selected from a group consisting of benzaldehyde, ethylene glycol, glycerol, butanedione, methyl vinyl ketone, acetyl acetone, cyclohexanone, fumaric acid dimethyl ester (C₆H₈O₄), polyvinyl pyrrolidone (C₆H₉NO)ₙ, polyvinyl alcohol (C₂H₄O)ₓ, 2-acrylic acid, 1-hydroxy propane-1,2,3-tricarboxylic acid, benzoic acid, and 2-hydroxy benzoic acid. In addition, the metal oxide composition may further include: 5-30 parts by weight of an adhesive agent, such as an organic polymer or an epoxy acrylate, 0-5 parts by weight of a dispersant, such as terpineol, or butyl cellosolve; 0.1-10 parts by weight of a plasticizer, such as phthalate esters, trimellitates, glycols, polyethers, or citrate esters, etc.; and 0-1 parts by weight of an additive, wherein the additive may be a curing agent (for example, amines, organic acids, or acid anhydrides), a flexibilizer (for example, dimethyl ester or triphenyl phosphate, and so on), or a diluent (for example, acetone, butanol, or glycol ether, and so on. The present invention also provides another embodiment of the conductive line, as shown in FIG. 2D. The manufacturing process thereof will be described with reference to FIGS. 2A-2D.

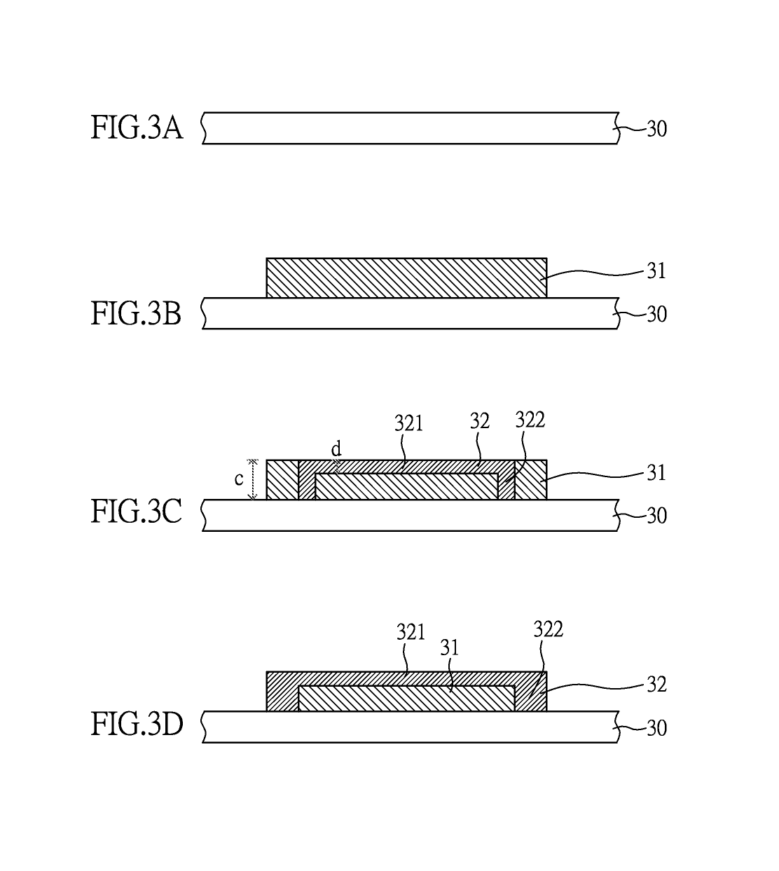

As shown in FIG. 2A, a substrate 20 is provided. In this embodiment, a glass substrate is used as an example, while other substrates as described above may also be used. A substrate having a planar structure is used as the example in this embodiment. Then, as shown in FIG. 2B, the metal oxide composition (not shown) having a different thickness is printed onto the substrate 20 by gravure printing , and cured by a thermal treatment to form a metal oxide layer 21. The formed metal oxide layer 21 has a first thickness a and a second thickness b. Next, as shown in FIG. 2C, a light radiation is performed with a photomask (not shown), wherein the light source may be the same as the above-described embodiment. As a result, the metal oxide in the irradiated portion of the metal oxide layer 21 is reduced into a corresponding metal form, to thereby form a patterned conductive line 22. FIG. 2D is a cross-section view along line A of the conductive line 22 shown in FIG. 2C, as shown in FIG. 2D, the thickness of the conductive line 22 may be adjusted by controlling the level of chemical reduction reaction of portion of the metal oxide layer 21. For example, the level of chemical reduction reaction of the metal oxide layer 21 may be adjusted by controlling the irradiation time or the intensity of the UV light. The present invention also provides yet another embodiment of the conductive line, as shown in FIG. 3C. The manufacturing process thereof will be described below with reference to FIGS. 3A-3C.

As shown in FIG. 3A, a substrate 30 is provided. In this embodiment, a glass substrate is used as an example, while other substrates as described above may also be used in other embodiments. The substrate having a planar structure is used as the example in this embodiment. Then, as shown in FIG. 3B, the metal oxide composition (not shown) is printed onto the substrate 30 by screen printing wherein the slurry of the metal oxide used herein is the same as the above embodiment, and cured by a thermal treatment to form a metal oxide layer 31. Then, a gray tone mask (not shown) is used as a mask to control the redox levels of different parts of the metal oxide layer 31, to form the conductive line 32 as shown in FIG. 3C. The resulting conductive line 32 includes the structures of the conductive lines 321 and 322, wherein the conductive line 322 receives a more sufficient amount of light under the modulation of the gray tone mask, and therefore, a higher level of chemical reduction reaction proceeds to form the conductive line 322 having a thickness c. On the other hand, the conductive line 321 receives a less sufficient amount of light under the modulation of the same gray tone mask, and thus a lower level of chemical reduction reaction proceeds to form the conductive line 321 having a thickness d. The structure combining the conductive lines 322 and 321 forms the conductive line 32 having a doorframe-like shape. FIG. 3D shows another embodiment of the conductive line prepared using a similar method, wherein the conductive line 32 is formed at the outer edge of the metal oxide layer 31 and partially covers the metal oxide layer 31.

In the above metal oxide composition, the reducing agent is added for reducing the metal oxide into the metal matrix under a light source with lower intensity. If the metal oxide compositions excludes a reducing agent, when the metal oxide powder is reduced into the metal matrix, high energy (e.g., >1000° C.) and specific gas atmosphere are required for performance of the reaction. Therefore, the reducing agent is added into the metal oxide composition of the present invention to reduce the energy required for reducing the metal oxide into the metal matrix. In addition, the reducing agent can further reduce the temperature of the overall process, thus reducing costs and simplifying the procedures.

The method for forming a conductive line of the present invention involves curing a metal oxide composition to form a metal oxide layer, and then using light irradiation to occur a chemical reduction reaction of the metal oxide into metal form, thereby forming a conductive line. Since the method for forming a conductive line of the present invention belongs to a low temperature process, the material of the substrate is less restrictive. Therefore, the method for forming a conductive line of the present invention may be applied to various electronic devices by persons skilled in the art, wherein the types of metal oxide or the solid content of the metal oxide may be further adjusted depending on the different applications, and the viscosity of the metal oxide composition may also be adjusted to co-operate with varying processes. For example, screen printing or gravure printing is suitable for metal oxide compositions having a high viscosity, and ink-jet printing is suitable metal oxide compositions having a low viscosity, to form a conductive line. In addition, the conductive line prepared by the method of the present invention has a minimum line width of 30 μm, showing a better resolution than that prepared by the conventional printing method, which has a minimum line width of about 70 μm. Furthermore, the present invention does not necessitate a photolithography and etching process, thereby accelerating the production speed, and reducing costs. Further, another advantage of the present invention is to form the conductive line in the metal oxide layer, that is, the metal oxide layer and the conductive line can be formed simultaneously, and various types of the conductive lines may also be formed in the metal oxide layer by the pre-selected photomask, such as the gray tone mask. Thus, the present invention is applicable to the manufacturing processes of the most electronic equipment, has a great utility in the industry, and represents a great advance in the manufacture of the conductive line.

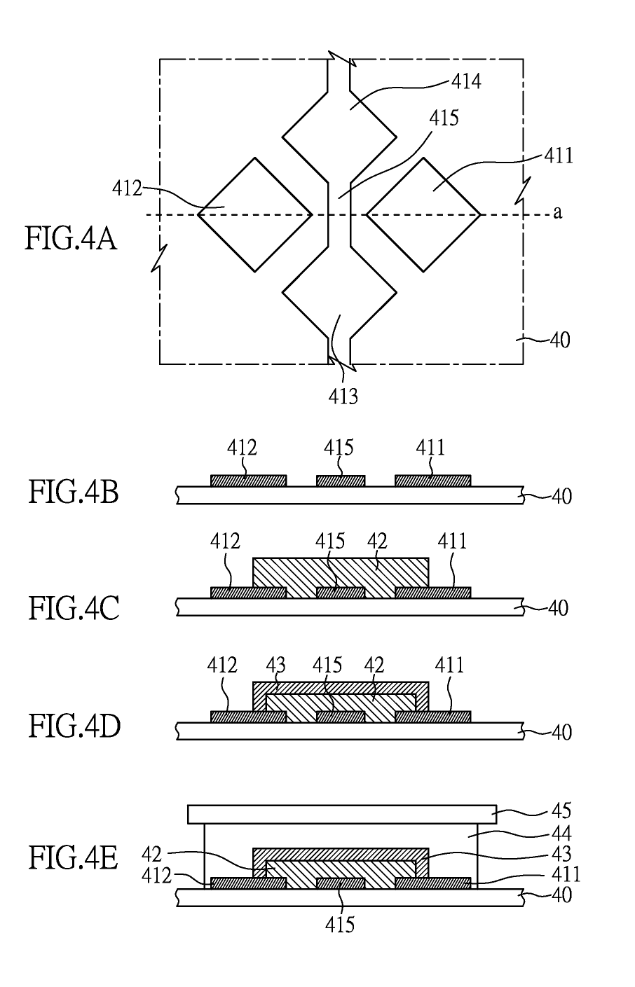

The present invention also provides an embodiment in which the above method of forming the conductive line is employed in a capacitive touch substrate. The manufacturing process thereof will be described below with reference to FIGS. 4A-4E.

As shown in FIG. 4A, a substrate 40 is provided. In this embodiment, a glass substrate is used as an example, while in other embodiments, the substrate is preferably an insulating substrate having a high transmittance, such as polycarbonate, poly(methyl propionate), or cyclic olefin, etc.. Then, a patterned electrode layer is formed on the substrate 40 by a photolithography and etching process, wherein the patterned electrode layer is made of ITO. In other embodiments, a patterned electrode layer may be made of a transparent electrode material known in the art. Herein, the patterned electrode layer comprises the first direction sub-electrodes 411 and 412 and the second direction sub-electrodes 413 and 414. As shown in FIG. 4A, the first direction sub-electrodes 411 and 412 are not electrically connected to each other, while the second direction sub-electrodes 413 and 414 electrically connect with each other through a connection layer 415. FIG. 4B is the cross-sectional view taken along the line a in FIG. 4A. Next, as shown in FIG. 4C, the metal oxide composition (not shown) is printed on a portion of the patterned electrode layer and a portion of the substrate by a printing method. The metal oxide composition is the same as that used in the above embodiment, and the metal oxide composition is cured by a thermal treatment to form a patterned metal oxide layer 42, contacting both of the first direction sub-electrodes 411 and 412 and the connection layer 415 between the second direction sub-electrodes 413 and 414. Then, as shown in FIG. 4D, the metal oxide in the metal oxide layer 42 is subjected to a redox reaction by light irradiation with a gray tone mask (not shown), to form a conductive bridging line 43. The conductive bridging line 43 is electrically connected to the first direction sub-electrodes 411 and 412, and electrically insulated to the connection layer 415 between the second direction sub-electrodes by a metal oxide layer 42. Then, as shown in FIG. 4E, a cover glass 45 is laminated to the above structure by an optical adhesive 44 to form a capacitive touch panel.

When the present method for forming the conductive line is employed in the manufacture of a capacitive touch panel, four acts of photolithography and etching processes as required in the conventional method can be simplified to only one act. In addition, the external circuit connecting the patterned electrode layer may be simultaneously formed during the formation of the conductive bridge layer, thereby further simplifying the manufacturing process of the capacitive touch panel. Therefore, the method of the present invention has advantages of simplified process, improved throughput, reduced costs, and reduced material waste, etc., representing a significant improvement in the manufacture of the capacitive touch panel.

It should be understood that these examples are merely illustrative of the present invention and the scope of the invention should not be construed to be defined thereby, and the scope of the present invention will be limited only by the appended claims.

What is claimed is:

1. A method for forming a conductive line, comprising:
(A) providing a metal oxide composition which comprises a metal oxide and a reducing agent, wherein the reducing agent is at least one selected from a group consisting of a polyol, a hydroxyl alcohol, an aldehyde, a ketone, and a carboxylic acid;
(B) applying the metal oxide composition on a substrate, and curing the metal oxide composition to form a metal oxide layer, wherein the metal oxide layer comprises the reducing agent; and
(C) irradiating the metal oxide layer through a light source to occur a chemical reduction reaction between the metal oxide and the reducing agent in the metal oxide layer and to form a conductive line.

2. The method of claim 1, wherein, in the step (A), the metal oxide composition comprises: 55-85 parts by weight of the metal oxide, and 5-15 parts by weight of the reducing agent.

3. The method of claim 1, wherein, in the step (A), the metal oxide is at least one selected from a group consisting of a gold oxide, a platinum oxide, a silver oxide, a copper oxide, a nickel oxide, an aluminum oxide, and a zinc oxide.

4. The method of claim 1, wherein, in the step (A), the reducing agent is at least one selected from a group consisting of benzaldehyde, ethylene glycol, glycerol, butanedione, methyl vinyl ketone, acetyl acetone, cyclohexanone, fumaric acid dimethyl ester, polyvinyl pyrrolidone, polyvinyl alcohol, 2-acrylic acid, 1-hydroxy propane-1,2,3-tricarboxylic acid, benzoic acid, and 2-hydroxy benzoic acid.

5. A device comprises:
a substrate; and
a conductive line, disposed on the substrate and formed by a metal reacting with a reducing agent, wherein the reducing agent is at least one selected from a group consisting of a polyol, a hydroxyl alcohol, an aldehyde, a ketone, and a carboxylic acid.

6. The device of claim 5, wherein the reducing agent is at least one selected from a group consisting of benzaldehyde, ethylene glycol, glycerol, butanedione, methyl vinyl ketone, acetyl acetone, cyclohexanone, fumaric acid dimethyl ester, polyvinyl pyrrolidone, polyvinyl alcohol, 2-acrylic acid, 1-hydroxy propane-1,2,3-tricarboxylic acid, benzoic acid, and 2-hydroxy benzoic acid.

7. The device of claim 5, wherein the device is a capacitive touch panel.

8. A device comprises:
a substrate;
a metal oxide layer disposed on the substrate, wherein the metal oxide layer comprises a metal oxide and a reducing agent, wherein the reducing agent is at least one selected from a group consisting of a polyol, a hydroxyl alcohol, an aldehyde, a ketone, and a carboxylic acid; and
a conductive line embedded in the metal oxide layer, wherein the conductive layer comprises a metal formed by a chemical reduction reaction of the metal oxide.

9. The device of claim 8, wherein the reducing agent is at least one selected from a group consisting of benzaldehyde, ethylene glycol, glycerol, butanedione, methyl vinyl ketone, acetyl acetone, cyclohexanone, fumaric acid dimethyl ester, polyvinyl pyrrolidone, polyvinyl alcohol, 2-acrylic acid, 1-hydroxy propane-1,2,3-tricarboxylic acid, benzoic acid, and 2-hydroxy benzoic acid.

10. The device of claim 8, wherein the device is a capacitive touch panel.
